(19) United States
(12) Patent Application Publication
(10) Pub. No.: US 2014/0374766 A1
(43) Pub. Date: Dec. 25, 2014

(54) BI-DIRECTIONAL GALLIUM NITRIDE SWITCH WITH SELF-MANAGED SUBSTRATE BIAS

(71) Applicant: Texas Instruments Incorporated, Dallas, TX (US)

(72) Inventors: Sandeep R. BAHL, Palo Alto, CA (US); Matthew SENESKY, Berkeley, CA (US); Naveen TIPIRNENI, Plano, TX (US); David I. ANDERSON, Saratoga, CA (US); Sameer PENDHARKAR, Allen, TX (US)

(21) Appl. No.: 13/922,352

(22) Filed: Jun. 20, 2013

(51) Int. Cl. H01L 27/06; H01L 29/20

(52) U.S. Cl. CPC H01L 27/0629; H01L 29/2003
USPC 257/76; 438/237

(57) ABSTRACT

A semiconductor device includes a bidirectional GaN FET formed on a non-insulating substrate. The semiconductor device further includes a first electrical clamp connected between the substrate and a first source/drain node of the bidirectional GaN FET, and a second electrical clamp connected between the substrate and a second source/drain node of the bidirectional GaN FET. The first clamp and the second clamp are configured to bias the substrate at a lower voltage level of an applied bias to the first source/drain node and an applied bias to the second source/drain node, within an offset voltage of the relevant clamp.

### FIELD OF THE INVENTION

This invention relates to the field of semiconductor devices. More particularly, this invention relates to gallium nitride field effect transistors in semiconductor devices.

### BACKGROUND OF THE INVENTION

Gallium nitride field effect transistors (GaN FETs) have desirable qualities for power switching applications. Integrating GaN FETs in a bidirectional switch on a common substrate may lead to undesirable performance tradeoffs.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

A semiconductor device includes a bidirectional GaN FET formed on a non-insulating substrate. The semiconductor device further includes a first electrical clamp connected between the substrate and a first source/drain node of the bidirectional GaN FET, and a second electrical clamp connected between the substrate and a second source/drain node of the bidirectional GaN FET. The first clamp and the second clamp are configured to bias the substrate at a lower voltage level of an applied bias to the first source/drain node and an applied bias to the second source/drain node, within an offset voltage of the relevant clamp.

### DESCRIPTION OF THE VIEWS OF THE DRAWING

FIG. 1 is a schematic of an exemplary semiconductor device containing a bidirectional GaN FET with clamps between source/drain nodes and a substrate.

FIG. 2 is a schematic of another exemplary semiconductor device containing a bidirectional GaN FET with clamps between source/drain nodes and a substrate.

FIG. 3 is a schematic of a further exemplary semiconductor device containing a bidirectional GaN FET with clamps between source/drain nodes and a substrate.

FIG. 4A through FIG. 4F are cross sections of an exemplary semiconductor device containing a bidirectional GaN FET and clamps, depicted in successive stages of fabrication.

FIG. 5A through FIG. 5E are cross sections of another exemplary semiconductor device containing a bidirectional GaN FET and clamps, depicted in successive stages of fabrication.

FIG. 6 is a cross section of an alternative form of the semiconductor device of FIG. 5E.

FIG. 7A through FIG. 7D are cross sections of a further exemplary semiconductor device containing a bidirectional GaN FET and clamps, depicted in successive stages of fabrication.

FIG. 8A and FIG. 8B are cross sections of an exemplary semiconductor device containing a bidirectional GaN FET, clamps and at least one pull-up/pull-down shunt, depicted in successive stages of fabrication.

FIG. 9 is a cross section of another exemplary semiconductor device containing a bidirectional GaN FET, clamps and at least one pull-up/pull-down shunt.

FIG. 10 is a cross section of an exemplary semiconductor device containing a bidirectional GaN FET with multiple pairs of gates, and two clamps.

### DETAILED DESCRIPTION OF EXAMPLE EMBODIMENTS

The present invention is described with reference to the attached figures. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

A semiconductor device includes a bidirectional GaN FET formed on a non-insulating substrate. The semiconductor device further includes a first electrical clamp connected between the substrate and a first source/drain node of the bidirectional GaN FET, and a second electrical clamp connected between the substrate and a second source/drain node of the bidirectional GaN FET. The first clamp and the second clamp are configured to bias the substrate at a lower voltage level of an applied bias to the first source/drain node and an applied bias to the second source/drain node, within an offset voltage of the relevant clamp.

For the purposes of this description, the term “III-N” is understood to refer to semiconductor materials in which group III elements, that is, aluminum, gallium and indium, and possibly boron, provide a portion of the atoms in the semiconductor material and nitrogen atoms provide the remainder of the atoms in the semiconductor material. Examples of III-N semiconductor materials are gallium nitride, boron gallium nitride, aluminum gallium nitride, indium nitride, and indium aluminum gallium nitride. Terms describing elemental formulas of materials do not imply a particular stoichiometry of the elements. III-N materials may be written with variable subscripts to denote a range of possible stoichiometries. For example, aluminum gallium nitride may be written as AlₓGa₁₋ₓN and indium aluminum gallium nitride may be written as InₓAl_{y}Ga_{1-x-y}N. For the purposes of this description, the term GaN FET is understood to refer to a field effect transistor which includes III-N semiconductor materials.

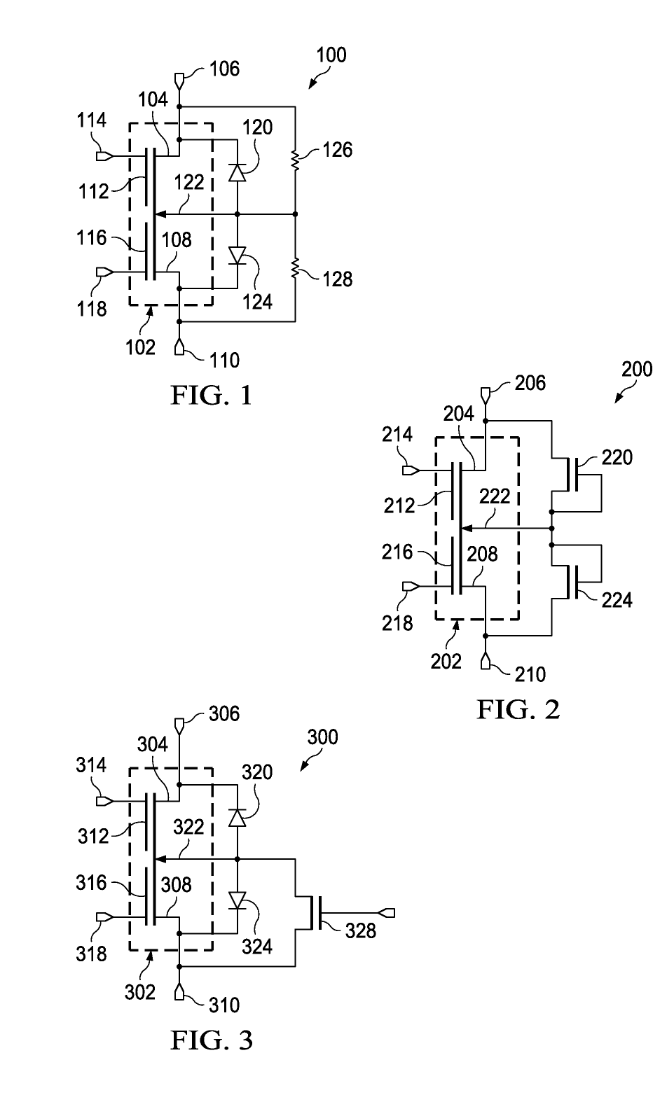

FIG. 1 is a schematic of an exemplary semiconductor device containing a bidirectional GaN FET with clamps between source/drain nodes and a substrate. The semiconductor device 100 includes a bidirectional GaN FET 102 formed on a non-insulating substrate 122. The bidirectional GaN FET 102 has a first source/drain node 104 connected to a first source/drain terminal 106 of the semiconductor device 100, and a second source/drain node 108 connected to a second source/drain terminal 110 of the semiconductor device 100. The bidirectional GaN FET 102 has a first gate 112 connected to a first gate terminal 114 of the semiconductor device 100, and a second gate 116 connected to a second gate terminal 118 of the semiconductor device 100. The semiconductor device 100 includes a first clamp 120 connected between a substrate node 122 of the bidirectional GaN FET 102 and the first source/drain node 104; in the instant example, the first clamp 120 is a first diode 120 with an anode of the first diode 120 connected to the substrate node 122 and a cathode of the first diode 120 connected to the first source/drain node 104. The semiconductor device 100 also includes a second clamp 124 connected between the substrate node 122 and the second source/drain node 108; in the instant example, the second clamp 124 is a second diode 124 with an anode connected to the substrate node 122 and a cathode connected to the second source/drain node 108.

The semiconductor device 100 may optionally include a first pull-up/pull-down shunt 126 connected in parallel across the first clamp 120 and/or a second pull-up/pull-down shunt 128 connected in parallel across the second clamp 124; in the instant example, the first pull-up/pull-down shunt 126 and the second pull-up/pull-down shunt 128 are resistors 126 and 128.

In a first mode of operation of the semiconductor device 100, the first source/drain terminal 106 may be biased to a higher potential than the second source/drain terminal 110. The second clamp 124 holds a potential of the substrate node 122 at the bias potential of the second source/drain terminal 110 plus an offset voltage of the second clamp 124. In the instant example, the offset voltage of the second clamp 124 is a forward bias turn-on voltage of the second diode 124. The first clamp 120 is reverse biased in the first mode of operation, so that the potential of the substrate node 122 is insensitive to the bias applied to the first source/drain terminal 106.

In a second mode of operation of the semiconductor device 100, the second source/drain terminal 110 may be biased to a higher potential than the first source/drain terminal 106. The first clamp 120 holds a potential of the substrate node 122 at the bias potential of the first source/drain terminal 106 plus an offset voltage of the first clamp 120, that is, a forward bias turn-on voltage of the first diode 120. The second clamp 124 is reverse biased in the second mode of operation, so that the potential of the substrate node 122 is insensitive to the bias applied to the second source/drain terminal 110.

During operation of the semiconductor device 100, it may occur that the potential of the substrate node 122 is pulled below both the potential of the first source/drain terminal 106 and the potential of the second source/drain terminal 110. In such an instance, current flow through the first pull-up/pull-down shunt 126 and/or the second pull-up/pull-down shunt 128 may advantageously speed up transition of the potential of the substrate node 122 to the desired value, that is the lower of the potential of the first source/drain terminal 106 and the potential of the second source/drain terminal 110. Resistance values of the first pull-up/pull-down shunt 126 and the second pull-up/pull-down shunt 128 may be selected to maintain current through the shunts 126 and 128 below desired levels.

FIG. 2 is a schematic of another exemplary semiconductor device containing a bidirectional GaN FET with clamps between source/drain nodes and a substrate. The semiconductor device 200 includes a bidirectional GaN FET 202 formed on a non-insulating substrate 222. The bidirectional GaN FET 202 has a first source/drain node 204 connected to a first source/drain terminal 206 of the semiconductor device 200, and a second source/drain node 208 connected to a second source/drain terminal 210 of the semiconductor device 200. The bidirectional GaN FET 202 has a first gate 212 connected to a first gate terminal 214 of the semiconductor device 200, and a second gate 216 connected to a second gate terminal 218 of the semiconductor device 200. The semiconductor device 200 includes a first clamp 220 connected between a substrate node 222 of the bidirectional GaN FET 202 and the first source/drain node 204; in the instant example, the first clamp 220 is a first enhancement mode field effect transistor (FET) 220 configured in a diode mode, with a source and a gate of the first FET 220 connected to the substrate node 222 and a drain of the first FET 220 connected to the first source/drain node 204 of the bidirectional GaN FET 102. The semiconductor device 200 also includes a second clamp 224 connected between the substrate node 222 and the second source/drain node 208; in the instant example, the second clamp 224 is a second enhancement mode FET 224 configured in a diode mode with a source and a gate of the second FET 224 connected to the substrate node 222 and a drain of the second FET 224 connected to the second source/drain node 208.

In a first mode of operation of the semiconductor device 200, the first source/drain terminal 206 may be biased to a higher potential than the second source/drain terminal 210. The second clamp 224 is in an on-state and holds a potential of the substrate node 222 at the bias potential of the second source/drain terminal 210 plus an offset voltage of the second clamp 224. In the instant example, the offset voltage of the second clamp 224 is a threshold voltage of the second FET 224. The first clamp 220 is in an off-state in the first mode of operation, so that the potential of the substrate node 222 is insensitive to the bias applied to the first source/drain terminal 206.

In a second mode of operation of the semiconductor device 200, the second source/drain terminal 210 may be biased to a higher potential than the first source/drain terminal 206. The first clamp 220 holds a potential of the substrate node 222 at the bias potential of the first source/drain terminal 206 plus a threshold voltage of the first FET 220, while the second FET 224 is in an off-state.

FIG. 3 is a schematic of a further exemplary semiconductor device containing a bidirectional GaN FET with clamps between source/drain nodes and a substrate. The semiconductor device 300 includes a bidirectional GaN FET 302 formed on a non-insulating substrate 322. The bidirectional GaN FET 302 has a first source/drain node 304 connected to a first source/drain terminal 306 of the semiconductor device 300, and a second source/drain node 308 connected to a second source/drain terminal 310 of the semiconductor device 300. The bidirectional GaN FET 302 has a first gate 312 connected to a first gate terminal 314 of the semiconductor device 300, and a second gate 316 connected to a second gate terminal 318 of the semiconductor device 300. The semiconductor device 300 includes a first clamp 320 connected between a substrate node 322 of the bidirectional GaN FET 302 and the first source/drain node 304; in the instant example, the first clamp 320 is a first diode 320 with an anode of the first diode 320 connected to the substrate node 322 and a cathode of the first diode 320 connected to the first source/drain node 304. The semiconductor device 300 also includes a second clamp 324 connected between the substrate node 322 and the second source/drain node 308; in the instant example, the second clamp 324 is a second diode 324 with an anode connected to the substrate node 322 and a cathode connected to the second source/drain node 308.

The semiconductor device 300 further includes a pull-up/pull-down shunt FET 328, for example a GaN FET 328 having a same threshold as the bidirectional GaN FET 302, connected between the substrate node 322 and the second source/drain node 308. A gate node of the pull-up/pull-down shunt FET 328 may be externally biased to a lower of a potential applied to the first gate terminal 314 and a potential applied to the second gate terminal 318. The enhancement mode GaN FET 328 may be integrated with the bidirectional GaN FET 302. The pull-up/pull-down shunt FET 328 may advantageously speed up transition of the potential of the substrate node 322 to the desired value, as described in reference to FIG. 1.

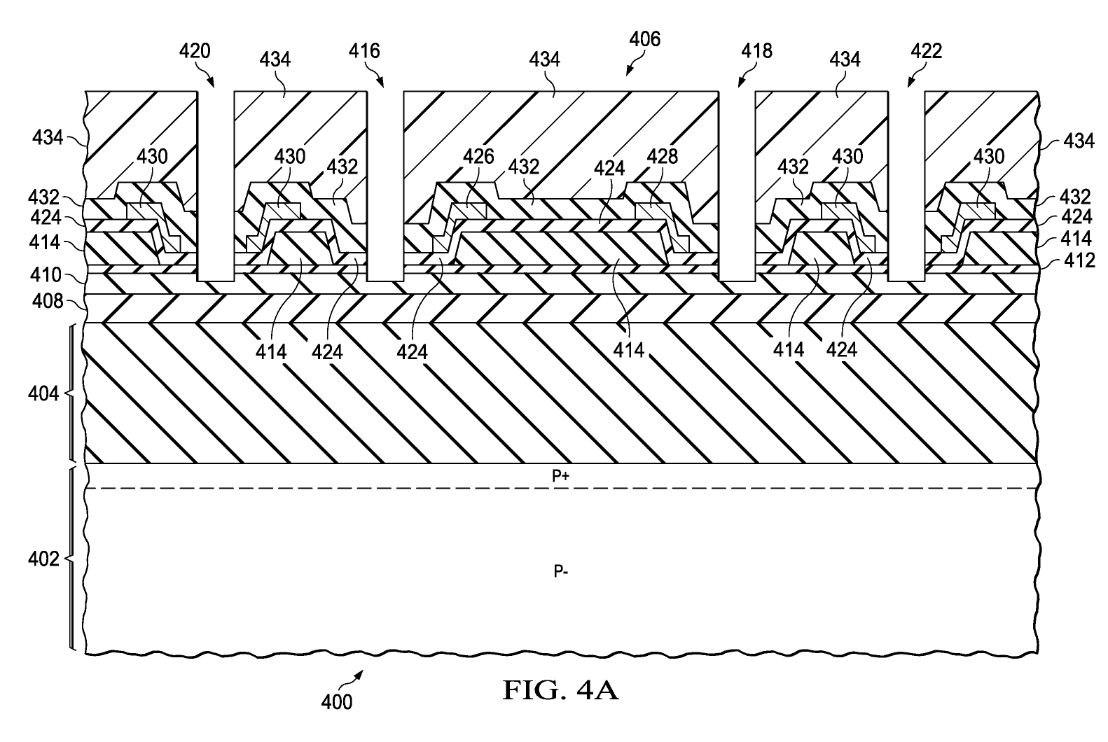

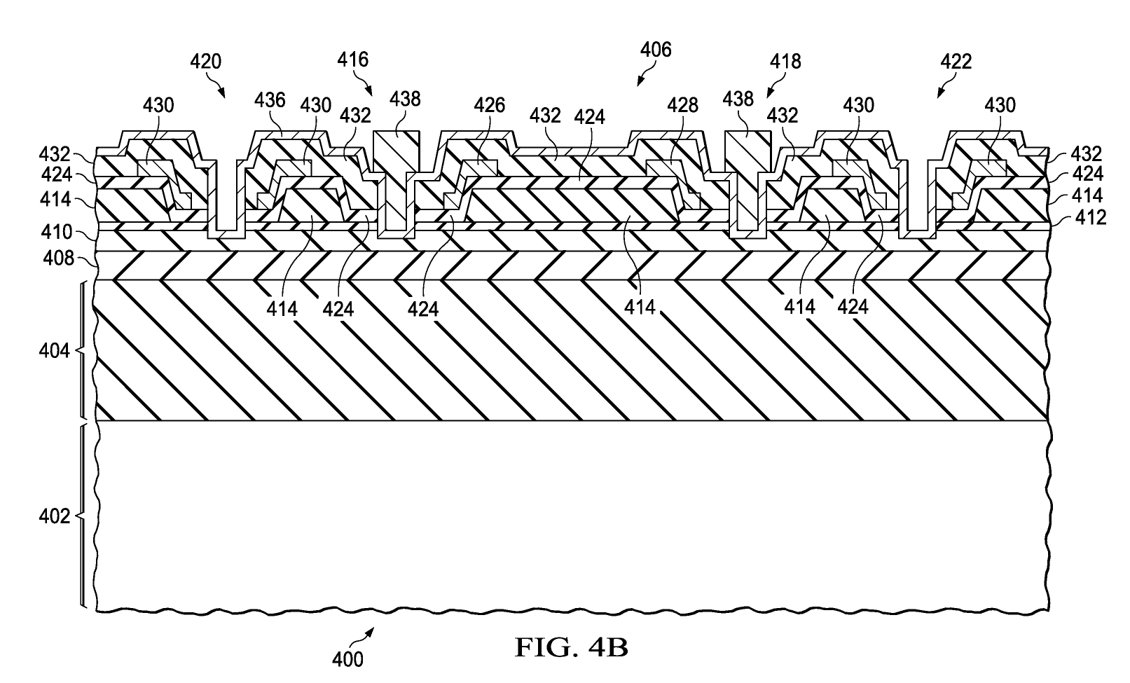

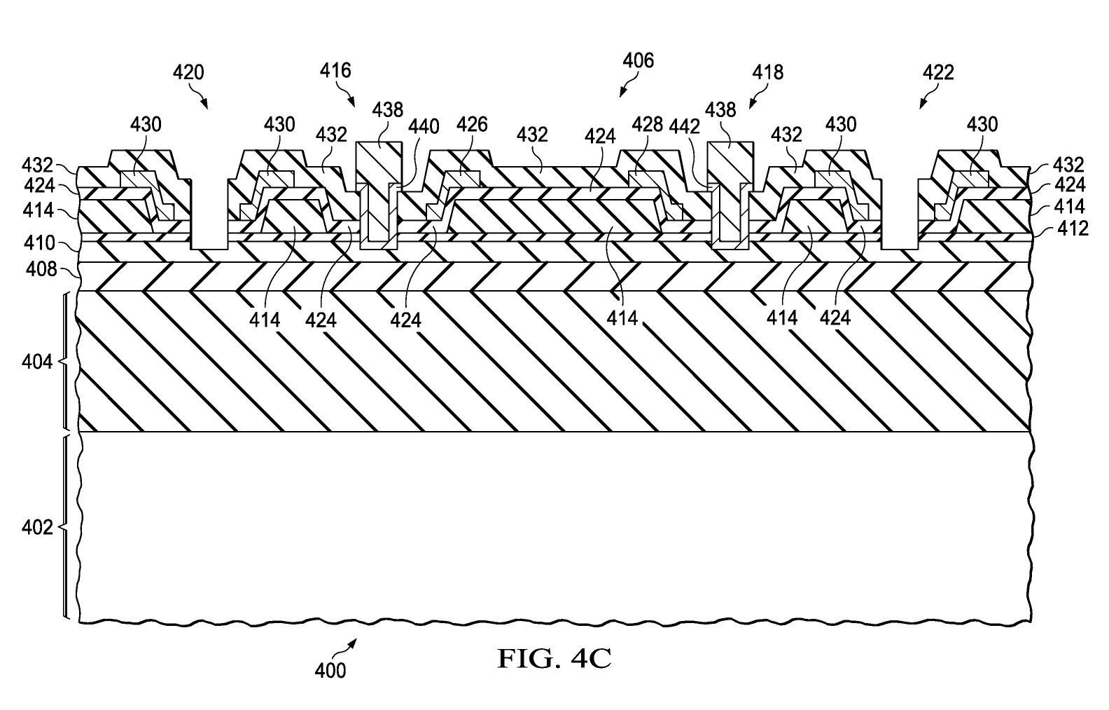

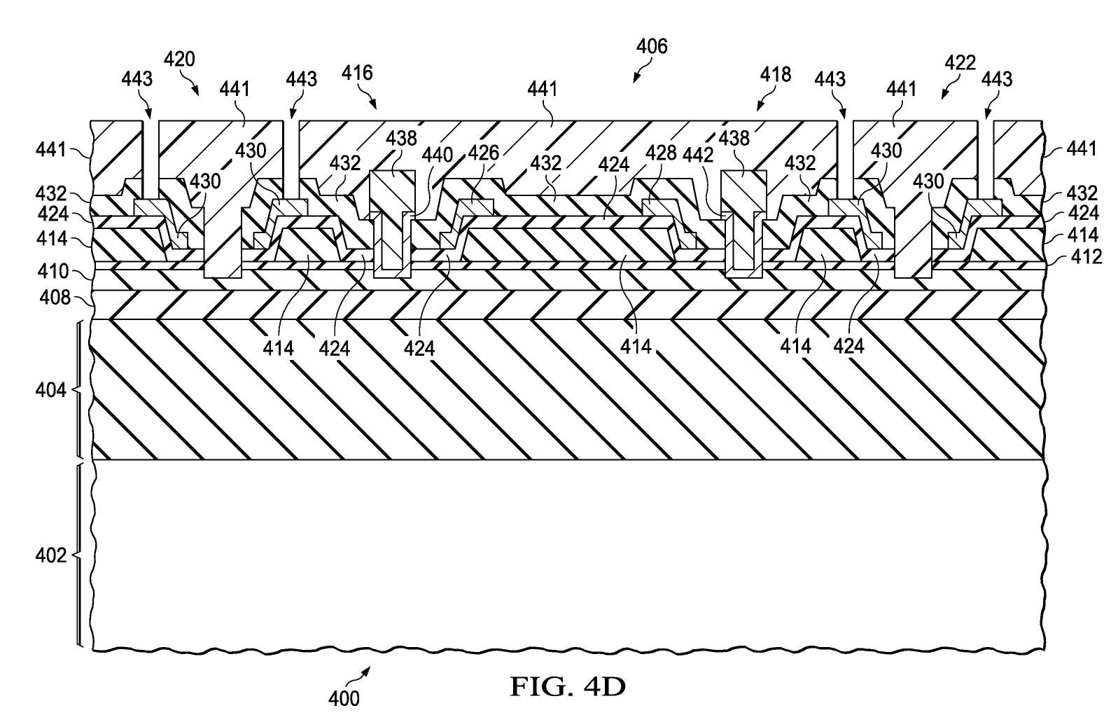

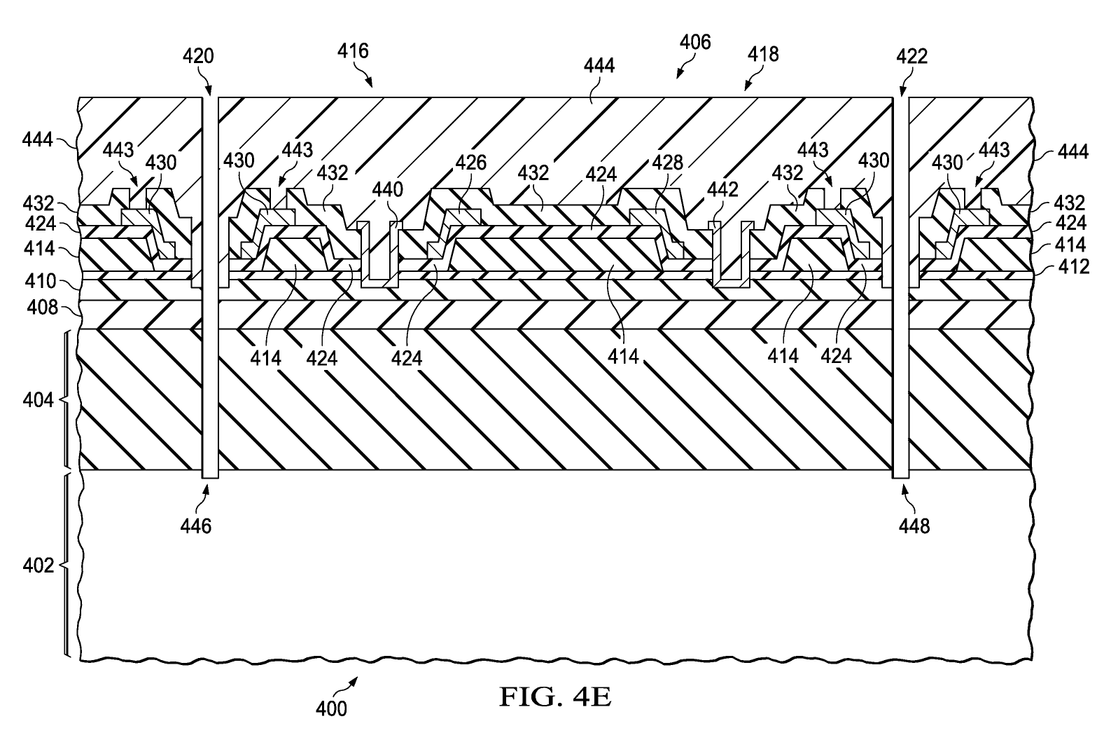

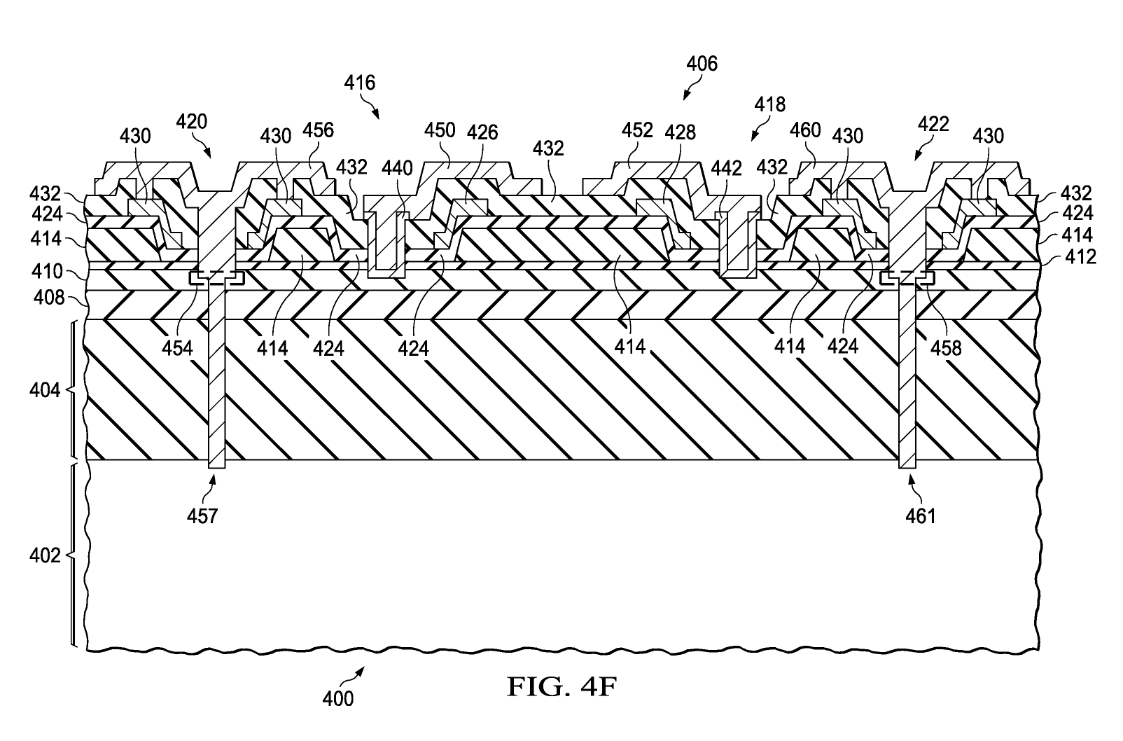

FIG. 4A through FIG. 4E are cross sections of an exemplary semiconductor device containing a bidirectional GaN FET and clamps, depicted in successive stages of fabrication. Referring to FIG. 4A, the semiconductor device 400 is formed on a non-insulating substrate 402 such as a silicon substrate. The substrate 402 may be, for example, a monolithic high resistivity silicon wafer, or a high resistivity wafer with a heavily doped layer at a top surface as depicted in FIG. 4A, or other non-insulating configuration. A III-N layer stack 404 is formed on the substrate 402 to provide a suitable surface for the bidirectional GaN FET 406. The III-N layer stack 404 may include, for example, a mismatch isolation layer of 100 to 300 nanometers of aluminum nitride formed on the substrate 402, a buffer layer of a stack 1 to 7 microns thick of graded layers of AlₓGa₁₋ₓN which is aluminum rich at the mismatch isolation layer and gallium rich at a top surface of the buffer layer, and an electrical isolation layer, possibly 300 nanometers to 2000 nanometers of semi-insulating gallium nitride, formed on the buffer layer.

A low-defect layer 408 is formed on the III-N layer stack 404. The low-defect layer 408 may be, for example, 25 to 1000 nanometers of gallium nitride. The low-defect layer 408 may be formed so as to minimize crystal defects which may have an adverse effect on electron mobility, which may result in the low-defect layer 408 being doped with carbon, iron or other dopant species, for example with a doping density less than 10¹⁷ cm⁻³.

A barrier layer 410 is formed on the low-defect layer 408. The barrier layer 410 may be, for example, 2 to 30 nanometers of AlₓGa₁₋ₓN or InₓAl_{y}Ga_{1-x-y}N. A composition of the barrier layer 410 may be, for example, 24 to 28 percent aluminum nitride and 72 to 76 percent gallium nitride. Forming the barrier layer 410 on the low-defect layer 408 generates a two-dimensional electron gas in the low-defect layer 408 just below the barrier layer 410 with an electron density of, for example, 1×10¹² to 2×10¹³ cm⁻². An optional cap layer 412 may be formed on the barrier layer 410. The cap layer 412 may be, for example, 2 to 5 nanometers of gallium nitride.

A first passivation layer 414 is formed and patterned over the barrier layer 410, on the cap layer 412 if present. The first passivation layer 414 may be, for example, 30 to 300 nanometers of silicon dioxide formed by a plasma enhanced chemical vapor deposition (PECVD) process using tetraethyl orthosilicate (TEOS) or silicon nitride formed by a low pressure chemical vapor deposition (LPCVD) process using dichlorosilane and ammonia. The first passivation layer 414 is patterned, for example by masking and etching using a reactive ion etch (RIE) process, to remove the first passivation layer 414 in an area for a first source/drain node 416 and an area for a second source/drain node 418 of the bidirectional GaN FET 406, and in an area for a first schottky diode clamp 420 and an area for a second schottky diode clamp 422 of the semiconductor device 400.

A gate dielectric layer 424 is formed over the barrier layer 410, on the cap layer 412 if present, where exposed by the first passivation layer 414. The gate dielectric layer 424 may be, for example, 10 to 30 nanometers of silicon nitride formed by an atomic layer deposition (ALD), an LPCVD or a PECVD process. In other version of the instant example, the gate dielectric layer 424 may include one or more layers of silicon nitride, silicon dioxide, silicon oxynitride and/or aluminum oxide.

A gate/field plate layer is formed and patterned over the gate dielectric layer 424 so as to form a first gate 426 and a second gate 428 of the bidirectional GaN FET 406, and form field plates 430 around the areas for the first schottky diode clamp and the second schottky diode clamp. The gate/field plate layer may be, for example, 100 to 300 nanometers of tungsten or titanium tungsten, and may be patterned using an etch process or a liftoff process. The first gate 426 and the second gate 428 may overlap the first passivation layer 414 as depicted in FIG. 4A. Similarly, the field plates 430 may overlap the first passivation layer 414.

A second passivation layer 432 is formed over the first gate 426, the second gate 428 and the field plates 430. The second passivation layer 432 may be, for example, 50 to 500 nanometers of silicon dioxide or silicon nitride formed by a PECVD process. A contact/diode etch mask 434 is formed over the second passivation layer 432 so as to expose the area for a first source/drain node 416 and the area for a second source/drain node 418 of the bidirectional GaN FET 406, and in the area for a first schottky diode clamp 420 and the area for a second schottky diode clamp 422 of the semiconductor device 400. The contact/diode etch mask 434 may include, for example, photoresist, formed by a photolithographic process. A contact hole etch process removes material from the second passivation layer 432, the gate dielectric layer 424, the cap layer 412 if present and the barrier layer 410 to form contact holes with bottoms in the barrier layer 410 proximate to the low-defect layer 408. The contact/diode etch mask 434 is removed after the contact hole etch process is completed.

Referring to FIG. 4B, a layer of contact metal 436 is formed over the second passivation layer 432, extending into the contact holes in the area for the first source/drain node 416 and the area for the second source/drain node 418 of the bidirectional GaN FET 406, and contacting the barrier layer 410. The layer of contact metal 436 may include, for example, sublayers of titanium and titanium nitride, formed by sputtering, ALD and/or chemical vapor deposition (CVD). A source/drain contact etch mask 438 is formed over the layer of contact metal 436 so as to cover the area for a first source/drain node 416 and the area for a second source/drain node 418, and to expose the area for a first schottky diode clamp 420 and the area for a second schottky diode clamp 422 of the semiconductor device 400.

Referring to FIG. 4C, a contact metal etch process removes the layer of contact metal 436 in areas exposed by the source/drain contact etch mask 438, including the contact holes in the area for a first schottky diode clamp 420 and the area for a second schottky diode clamp 422, so as to form a first source/drain contact 440 in the contact holes in the area for the first source/drain node 416 and form a second source/drain contact 442 in the contact holes in the area for the second source/drain node 418. The first source/drain contact 440 and the second source/drain contact 442 make contact with the barrier layer 410. The source/drain contact etch mask 438 is removed after the contact metal etch process is completed. After the source/drain contact etch mask 438 is removed, an anneal process is performed which heats the first source/drain contact 440 and the second source/drain contact 442 and the barrier layer 410 so that the first source/drain contact 440 and the second source/drain contact 442 provide ohmic contacts to the two-dimensional electron gas in the low-defect layer 408. The anneal process is performed while the contact holes in the area for a first schottky diode clamp 420 and the area for a second schottky diode clamp 422 are free of contact metal.

Referring to FIG. 4D, a field plate via etch mask 441 is formed over the second passivation layer 432, so as to expose areas for field plate vias 443. A field plate via etch process removes material from the second passivation layer 432 so as to expose the field plates 430. The field plate via etch mask 441 is removed after the field plate via etch process is completed.

Referring to FIG. 4E, a clamp via etch mask 444 is formed over the second passivation layer 432, so as to expose areas for clamp vias inside the contact holes in the area for a first schottky diode clamp 420 and the area for a second schottky diode clamp 422. The clamp via etch mask 444 may include, for example, photoresist, formed by a photolithographic process, and may optionally include a hard mask layer, not shown. A clamp via etch process removes material from the barrier layer 410, the low-defect layer 408 and the III-N layer stack 404, to form a first clamp via hole 446 which exposes the substrate 402 in the area for the first schottky diode clamp 420 and form a second clamp via hole 448 which exposes the substrate 402 in the area for the second schottky diode clamp 422. The clamp via etch mask 444 is removed after the clamp via etch process is completed.

Referring to FIG. 4F, interconnect metal is formed and patterned over the second passivation layer 432, making an electrical connection to the first source/drain contact 440 so as to form a first source/drain interconnect 450 and making an electrical connection to the second source/drain contact 442 so as to form a second source/drain interconnect 452. The patterned interconnect metal also includes a first clamp interconnect 456 which makes an electrical connection to the barrier layer 410 to form a first schottky diode 454 in the area for the first schottky diode clamp 420 and extends into the first clamp via hole 446 to make a first clamp via 457 which makes an electrical connection to the substrate 402. The patterned interconnect metal further includes a second clamp interconnect 460 which makes an electrical connection to the barrier layer 410 to form a second schottky diode 458 in the area for the second schottky diode clamp 422 and extends into the second clamp via hole 448 to make a second clamp via 461 which makes an electrical connection to the substrate 402. The first schottky diode 454 and the first clamp interconnect 456 provide the first schottky diode clamp 420 of the semiconductor device 400. Similarly, the second schottky diode 458 and the second clamp interconnect 460 provide the second schottky diode clamp 422 of the semiconductor device 400.

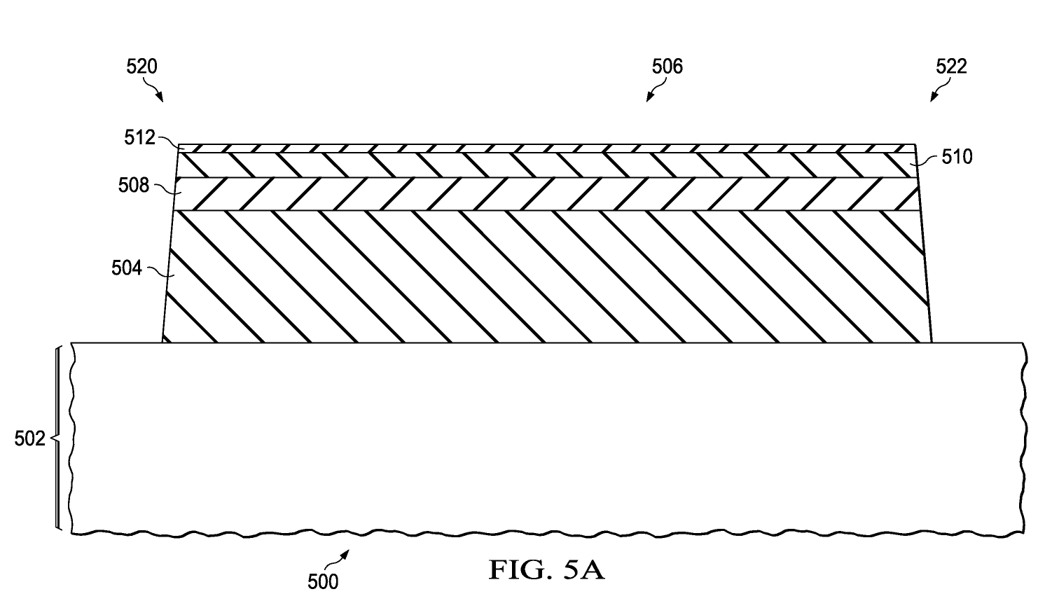

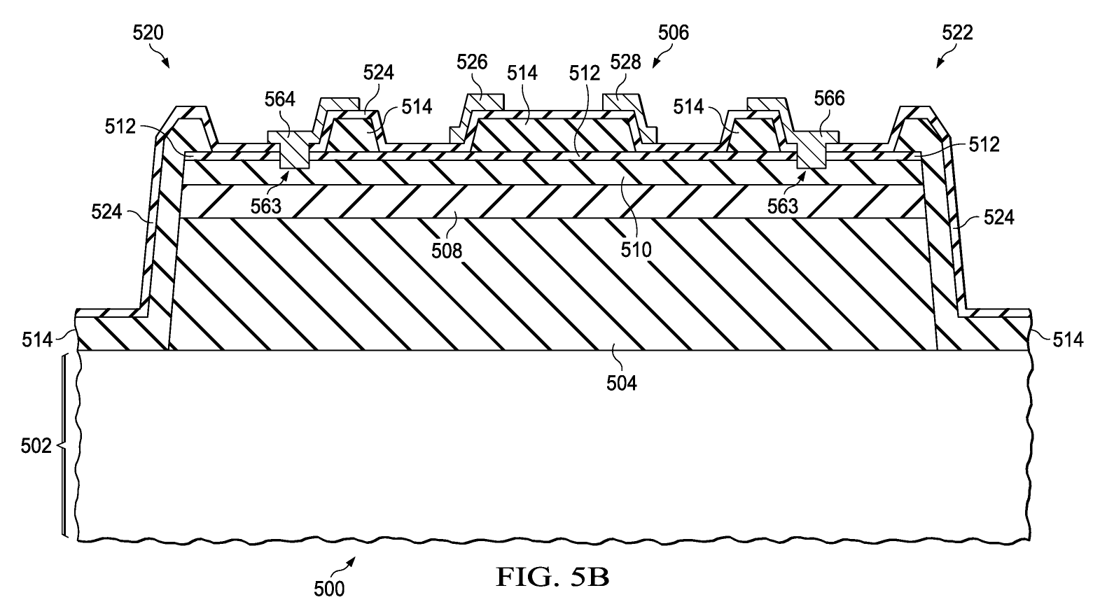

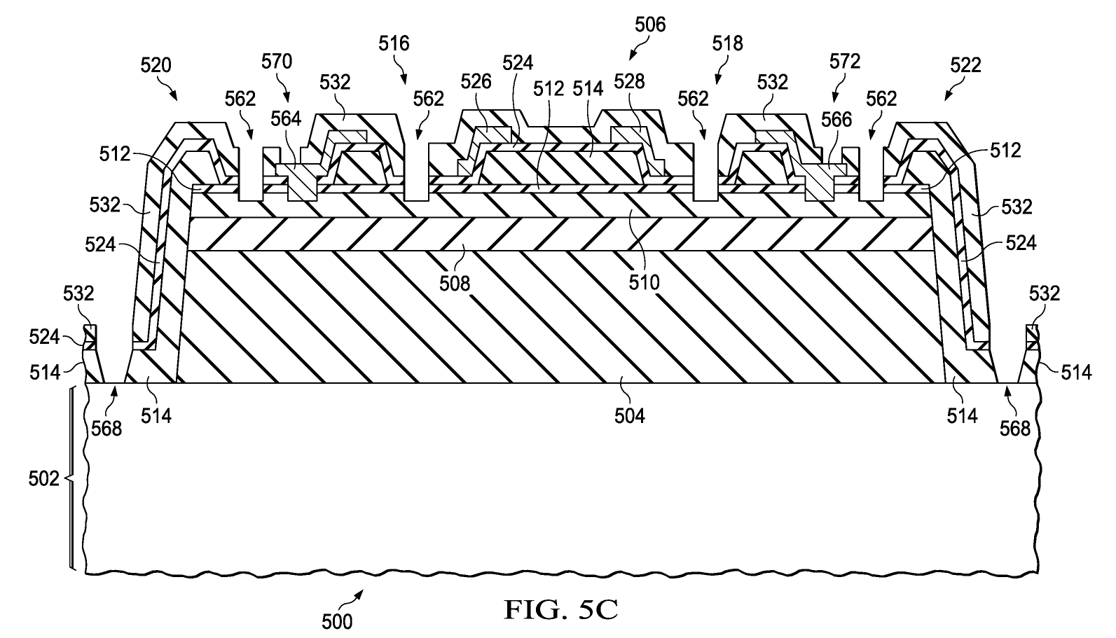

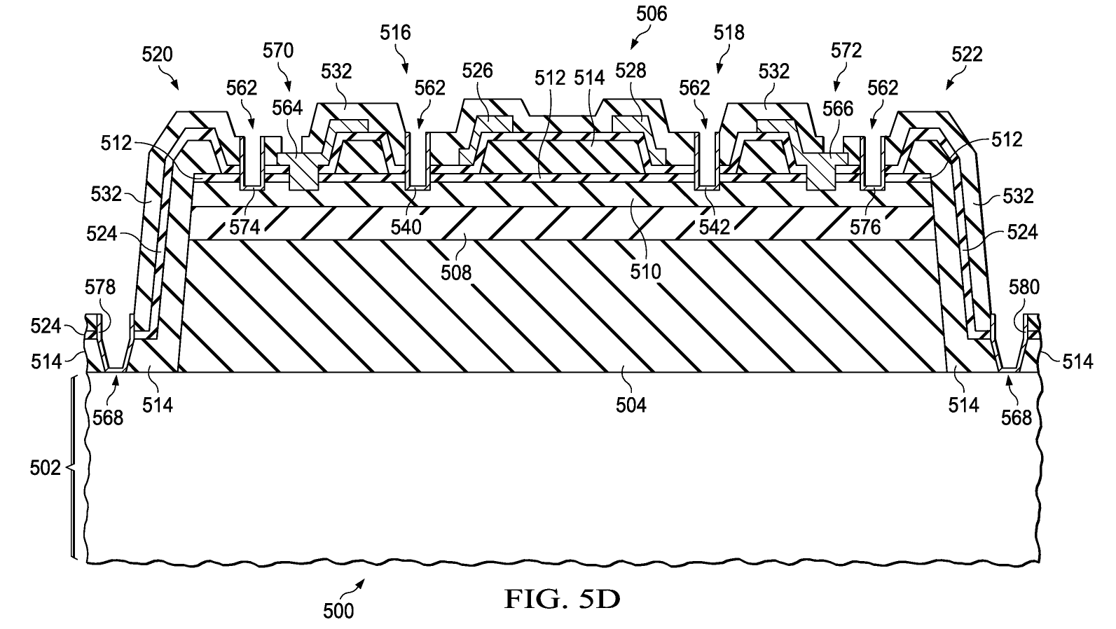

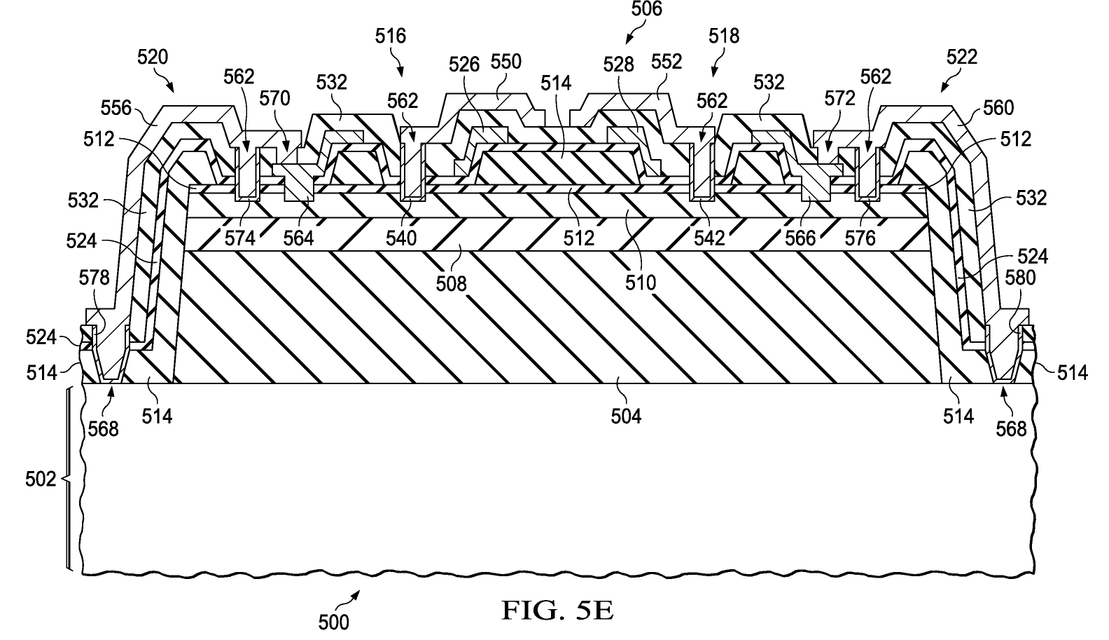

FIG. 5A through FIG. 5E are cross sections of another exemplary semiconductor device containing a bidirectional GaN FET and clamps, depicted in successive stages of fabrication. Referring to FIG. 5A, the semiconductor device 500 is formed on a non-insulating substrate 502 such as a silicon substrate. A III-N layer stack 504 is formed on the substrate 502 to provide a suitable surface for the bidirectional GaN FET 506. A low-defect layer 508 is formed on the III-N layer stack 504. A barrier layer 510 is formed on the low-defect layer 508. Forming the barrier layer 510 on the low-defect layer 508 generates a two-dimensional electron gas in the low-defect layer 508 just below the barrier layer 510. An optional cap layer 512 may be formed on the barrier layer 510. The III-N layer stack 504, the low-defect layer 508, the barrier layer 510 and the cap layer 512 may be, for example, similar to the III-N layer stack 404, the low-defect layer 408, the barrier layer 410 and the cap layer 412, respectively, of FIG. 4A.

An isolation etch process removes the cap layer 512, the barrier layer 510, the low-defect layer 508 and the III-N layer stack 504 outside an area for the bidirectional GaN FET 506, possibly exposing the substrate 502. The isolation etch process may, for example, use an etch mask of photoresist followed by a wet etch process. The cap layer 512, the barrier layer 510, the low-defect layer 508 and the III-N layer stack 504 are removed in a portion of an area for a first FET clamp 520 and in a portion of an area for a second FET clamp 522 of the semiconductor device 500.

Referring to FIG. 5B, a first passivation layer 514 is formed over the cap layer 512, the barrier layer 510, the low-defect layer 508 and the III-N layer stack 504, overlapping onto the substrate 502, so as to cover sides of the cap layer 512, the barrier layer 510, the low-defect layer 508 and the III-N layer stack 504 which were exposed by the isolation etch process of FIG. 5A. The first passivation layer 514 may be formed as a conformal layer, so that a thickness of the first passivation layer 514 on the exposed sides of the cap layer 512, the barrier layer 510, the low-defect layer 508 and the III-N layer stack 504 is at least 50 percent of a thickness of the first passivation layer 514 on the substrate 502 and on the cap layer 512.

The first passivation layer 514 is patterned so as to remove the first passivation layer 514 in an area for a first source/drain node 516 and an area for a second source/drain node 518 of the bidirectional GaN FET 506, and in a portion of the area for the first FET clamp 520 over the barrier layer 510 and in a portion of the area for the second FET clamp 522 over the barrier layer 510. The first passivation layer 514 is not removed from the exposed sides of the cap layer 512, the barrier layer 510, the low-defect layer 508 and the III-N layer stack 504.

A gate dielectric layer 524 is formed over the first passivation layer 514 and over the barrier layer 510, on the cap layer 512 if present, where exposed by the first passivation layer 514. The gate dielectric layer 524 may be formed, for example, as described in reference to FIG. 4A.

Recesses 563 are formed through the gate dielectric layer 524 and the cap layer 512 and extending into the barrier layer 510 in area for gates of the first FET clamp 520 and the second FET clamp 522. A gate/field plate layer is formed and patterned over the gate dielectric layer 524 so as to form a first gate 526 and a second gate 528 of the bidirectional GaN FET 506, and form an enhancement mode first clamp gate 564 in the area for the first FET clamp 520 and an enhancement mode second clamp gate 566 in the area for the second FET clamp 522. The enhancement mode first clamp gate 564 and the enhancement mode second clamp gate 566 extend into the recesses 563 and overlap the first passivation layer 514 adjacent to the recesses 563.

Referring to FIG. 5C, second passivation layer 532 is formed over the first gate 526, the second gate 528, the first clamp gate 564 and the second clamp gate 566, and overlapping the substrate 502 in the area for the first FET clamp 520 and in the area for the second FET clamp 522. The second passivation layer 532 may be formed, for example, as described in reference to FIG. 4A.

A contact etch process is performed which removes the second passivation layer 532, the gate dielectric layer 524, the cap layer 512 and a portion of the barrier layer 510 to form two-dimensional electron gas (2DEG) contact holes 562 in the area for the first source/drain node 516 and the area for the second source/drain node 518, and in the area for the first FET clamp 520 and the area for the second FET clamp 522. The contact etch process also forms substrate vias 568 through the second passivation layer 532, the gate dielectric layer 524 and the first passivation layer 514 so as to expose the substrate 502 in the area for the first FET clamp 520 and in the area for the second FET clamp 522. The contact etch process may further form a first gate contact via 570 through the second passivation layer 532 to expose the first clamp gate 564 and a second gate contact via 572 through the second passivation layer 532 to expose the second clamp gate 566. Alternatively, the first gate contact via 570 and the second gate contact via 572 may be formed separately in another etch process. The contact etch process may be performed, for example, by forming an etch mask of photoresist followed by a wet etch.

Referring to FIG. 5D, a layer of contact metal is formed over the second passivation layer 532, extending into the 2DEG contact holes 562 and the substrate vias 568, and is subsequently patterned to form a first source/drain contact 540 in the 2DEG contact holes 562 in the area for the first source/drain node 516, a second source/drain contact 542 in the 2DEG contact holes 562 in the area for the second source/drain node 518, a first FET clamp contact 574 in the 2DEG contact holes 562 in the area for the first FET clamp 520, and a second FET clamp contact 576 in the 2DEG contact holes 562 in the area for the second FET clamp 522, and optionally a first substrate clamp contact 578 in the substrate vias 568 in the area for the first FET clamp 520, and a second substrate clamp contact 580 in the substrate vias 568 in the area for the second FET clamp 522. Subsequently, an anneal process is performed which heats the first source/drain contact 540, the second source/drain contact 542, the first FET clamp contact 574, the second FET clamp contact 576 and the barrier layer 510 so that the first source/drain contact 540, the second source/drain contact 542, the first FET clamp contact 574, the second FET clamp contact 576 provide ohmic contacts to the two-dimensional electron gas in the low-defect layer 508.

Referring to FIG. 5E, interconnect metal is formed and patterned over the second passivation layer 532, making an electrical connection to the first source/drain contact 540 so as to form a first source/drain interconnect 550 and making an electrical connection to the second source/drain contact 542 so as to form a second source/drain interconnect 552. The patterned interconnect metal also includes a first clamp interconnect 556 which makes an electrical connection to the first clamp gate 564 through the first gate contact via 570, to the first FET clamp contact 574, and to the substrate 502 through the first substrate clamp contact 578 if present. The patterned interconnect metal further includes a second clamp interconnect 560 which makes an electrical connection to the second clamp gate 566 through the second gate contact via 572, to the second FET clamp contact 576, and to the substrate 502 through the second substrate clamp contact 580 if present. The first clamp gate 564, the first FET clamp contact 574, the first substrate clamp contact 578 and the first clamp interconnect 556 provide the first clamp 520 of the semiconductor device 500. Similarly, the second clamp gate 566, the second FET clamp contact 576, the second substrate clamp contact 580 and the second clamp interconnect 560 provide the second clamp 522.

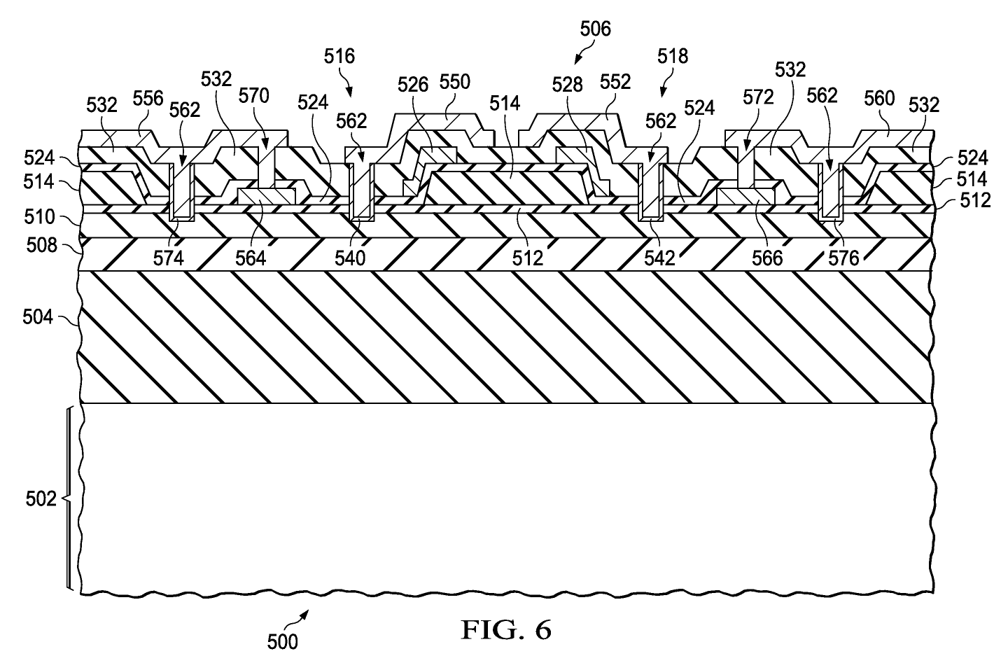

FIG. 6 is a cross section of an alternative form of the semiconductor device 500 of FIG. 5E. The enhancement mode first clamp gate 564 and the enhancement mode second clamp gate 566 are formed of p-type III-N material such as p-type gallium nitride, and are formed on the cap layer 512. The gate dielectric layer 524 is formed after the enhancement mode first clamp gate 564 and the enhancement mode second clamp gate 566 are formed and covers the enhancement mode first clamp gate 564 and the enhancement mode second clamp gate 566.

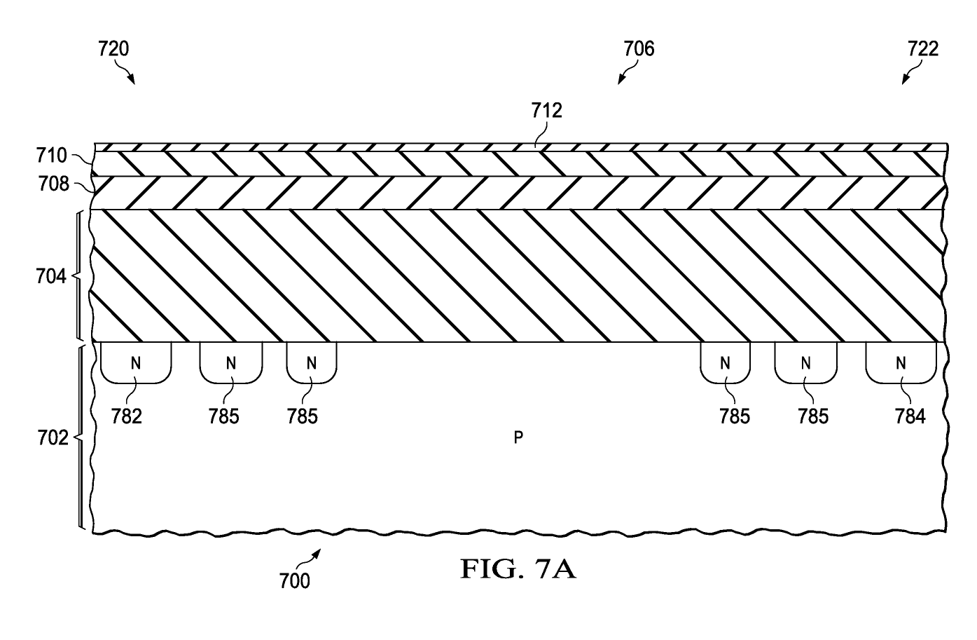

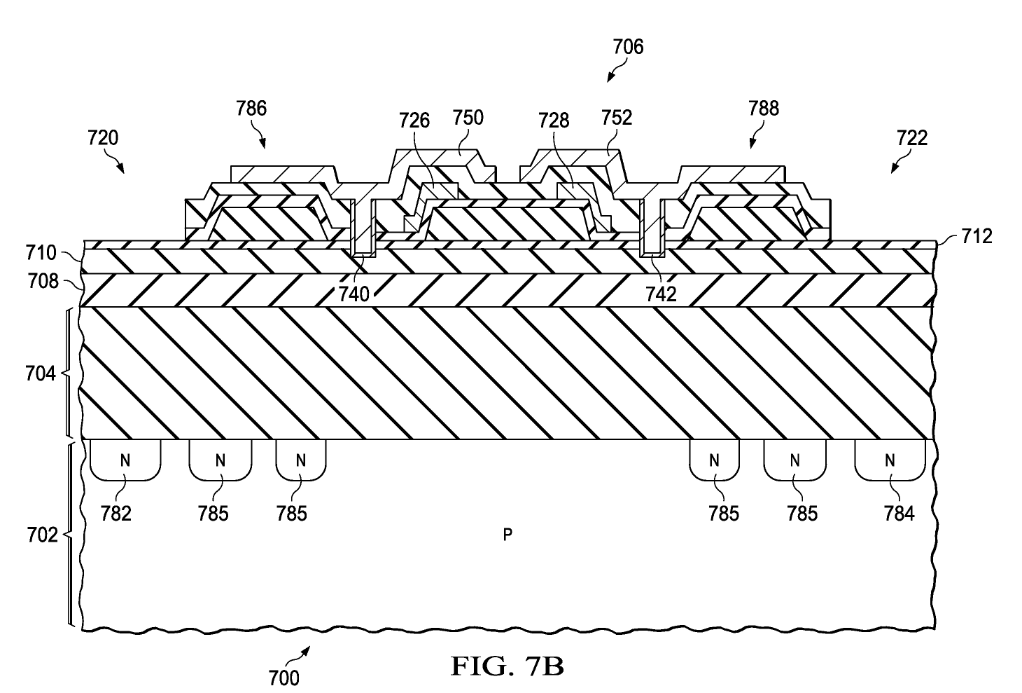

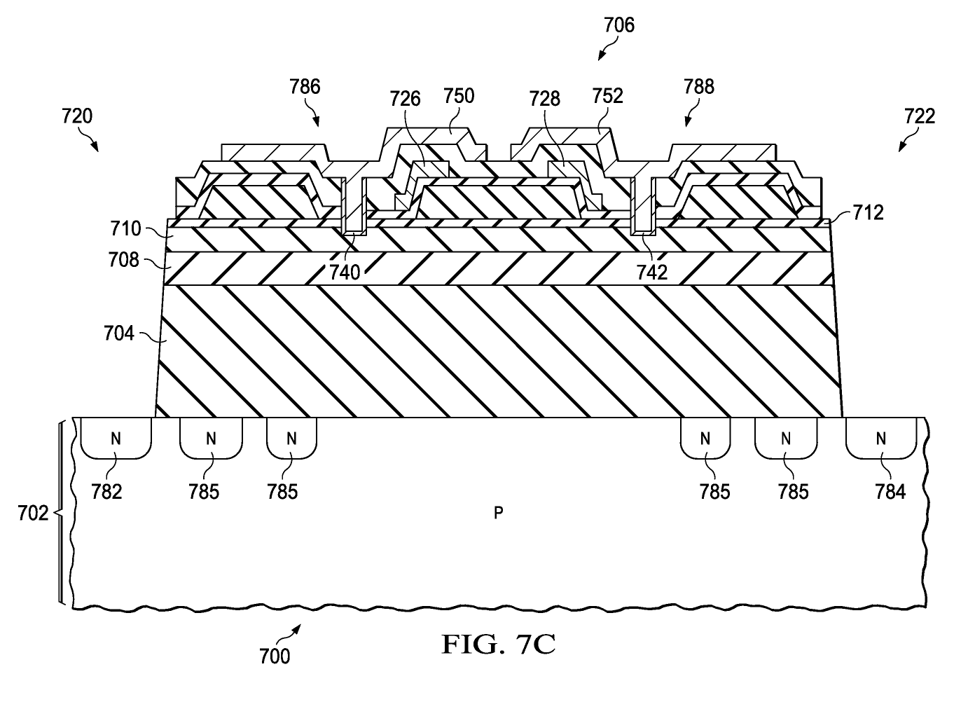

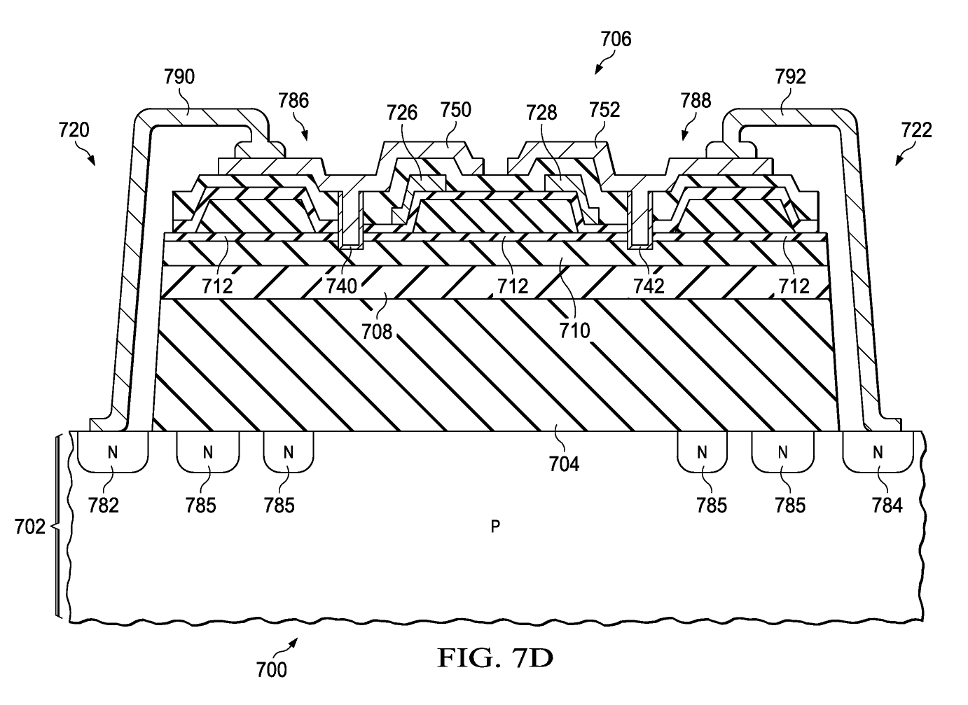

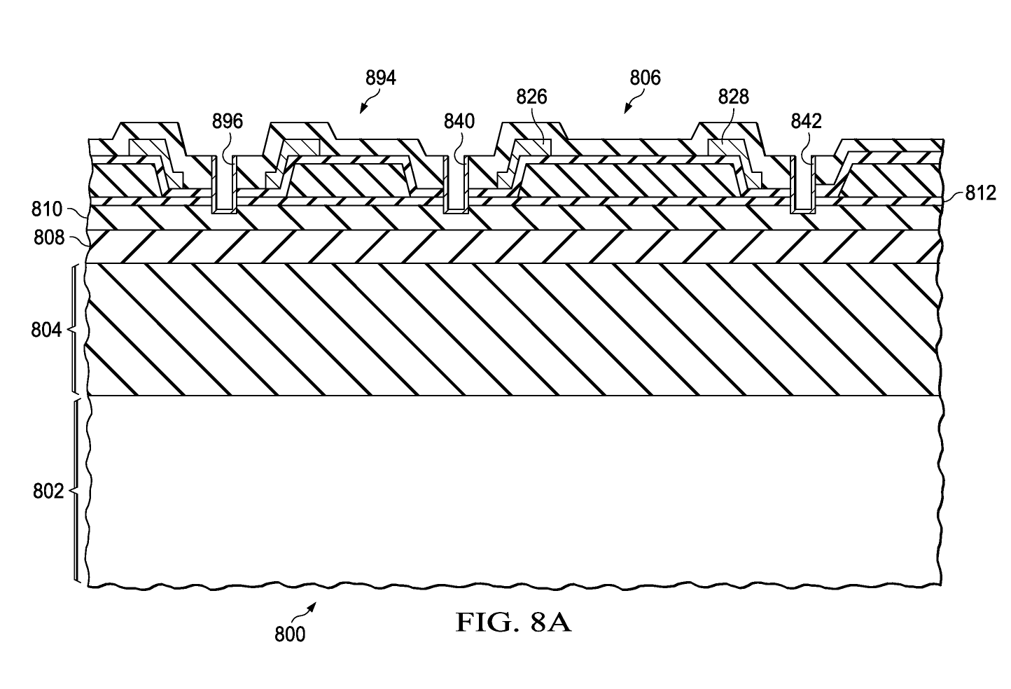

FIG. 7A through FIG. 7D are cross sections of a further exemplary semiconductor device containing a bidirectional GaN FET and clamps, depicted in successive stages of fabrication. Referring to FIG. 7A, the semiconductor device 700 is formed on a semiconductor substrate 702 such as a p-type silicon substrate. The substrate 702 has a first clamp diode 782 in the form of a diffused n-type region 782 in an area for a first diode clamp 720 of the semiconductor device 700 and has a second clamp diode 784 in an area for a second diode clamp 722 in the form of a diffused n-type region 784 of the semiconductor device 700. An anode of the first clamp diode 782 and an anode of the second clamp diode 784 are directly electrically connected to a portion of the substrate 702 under the GaN FET 706. Additional n-type diffused regions 785 are formed proximate to the first clamp diode 782 and the second clamp diode 784 so as to provide a depletion region in the substrate 702 when large biases are applied to the semiconductor device 700.

A III-N layer stack 704 is formed on the substrate 702 to provide a suitable surface for the bidirectional GaN FET 706. A low-defect layer 708 is formed on the III-N layer stack 704. A barrier layer 710 is formed on the low-defect layer 708. Forming the barrier layer 710 on the low-defect layer 708 generates a two-dimensional electron gas in the low-defect layer 708 just below the barrier layer 710. An optional cap layer 712 may be formed on the barrier layer 710. The III-N layer stack 704, the low-defect layer 708, the barrier layer 710 and the cap layer 712 may be, for example, similar to the III-N layer stack 404, the low-defect layer 408, the barrier layer 410 and the cap layer 412, respectively, of FIG. 4A.

Referring to FIG. 7B, the bidirectional GaN FET 706 is formed in and over the barrier layer 710, for example, as described in reference to FIG. 4A through FIG. 4E or in reference to FIG. 5A through FIG. 5E. The bidirectional GaN FET 706 includes a first gate 726 and a second gate 728, and a first source/drain contact 740 and a second source/drain contact 742. The bidirectional GaN FET 706 further includes a first source/drain interconnect 750 which makes an electrical connection to the first source/drain contact 740 and a second source/drain interconnect 752 which makes an electrical connection to the second source/drain contact 742. The first source/drain interconnect 750 includes a first clamp bonding pad 786 in the area for the first diode clamp 720; the second source/drain interconnect 752 includes a second bonding pad 788 in the area for the second diode clamp 722.

Referring to FIG. 7C, an isolation etch process removes the cap layer 712, the barrier layer 710, the low-defect layer 708 and the III-N layer stack 704 outside an area for the bidirectional GaN FET 706, exposing the substrate 702 at the first clamp diode 782 and the second clamp diode 784. The isolation etch process may be performed, for example, as described in reference to FIG. 5A.

Referring to FIG. 7D, a first electrical connection 790, for example a wirebond 790 as depicted in FIG. 7D, is formed so as to connect the first clamp bonding pad 786 of the first source/drain interconnect 750 to a cathode of the first clamp diode 782. A second electrical connection 792 is formed so as to connect the second clamp bonding pad 788 of the second source/drain interconnect 752 to a cathode of the second clamp diode 784. The first clamp bonding pad 786, the first electrical connection 790, and the first clamp diode 782 provide the first clamp 720 of the semiconductor device 700. The second clamp bonding pad 788, the second electrical connection 792, and the second clamp diode 784 provide the second clamp 722.

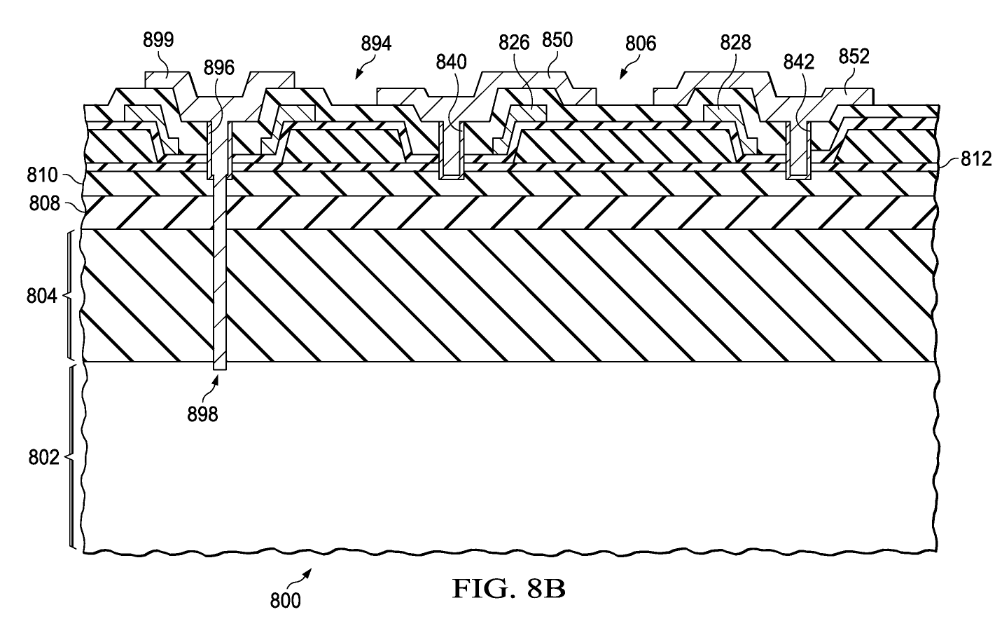

FIG. 8A and FIG. 8B are cross sections of an exemplary semiconductor device containing a bidirectional GaN FET, clamps and at least one pull-up/pull-down shunt, depicted in successive stages of fabrication. Referring to FIG. 8A, the semiconductor device 800 is formed on a non-insulating substrate 802 such as a silicon substrate. A III-N layer stack 804 is formed on the substrate 802 to provide a suitable surface for the bidirectional GaN FET 806. A low-defect layer 808 is formed on the III-N layer stack 804. A barrier layer 810 is formed on the low-defect layer 808. Forming the barrier layer 810 on the low-defect layer 808 generates a two-dimensional electron gas in the low-defect layer 808 just below the barrier layer 810. An optional cap layer 812 may be formed on the barrier layer 810. The III-N layer stack 804, the low-defect layer 808, the barrier layer 810 and the cap layer 812 may be, for example, similar to the III-N layer stack 404, the low-defect layer 408, the barrier layer 410 and the cap layer 412, respectively, of FIG. 4A.

The bidirectional GaN FET 806 is formed in and over the barrier layer 810, for example, as described in reference to FIG. 4A through FIG. 4E or in reference to FIG. 5A through FIG. 5E. The bidirectional GaN FET 806 includes a first gate 826 and a second gate 828, and a first source/drain contact 840 and a second source/drain contact 842.

The semiconductor device 800 further includes the pull-up/pull-down shunt 894 which in the instant example is a resistor 894 with a resistor body in the two-dimensional electron gas in the low-defect layer 808. The first source/drain contact 840 provides a source-side resistor contact to the resistor body. The pull-up/pull-down shunt 894 includes a substrate-side resistor contact 896 in the form of an ohmic contact 896 to the resistor body; the substrate-side resistor contact 896 may be formed concurrently with the first source/drain contact 840 and the second source/drain contact 842.

Referring to FIG. 8B, a shunt via 898 is formed by a via etch process which removes material from the barrier layer 810, the low-defect layer 808 and the III-N layer stack 804, and exposes the substrate 802. The shunt via 898 may be formed similarly to the first clamp via hole 446 as described in reference to FIG. 4D. A first source/drain interconnect 850 is formed which makes an electrical connection to the first source/drain contact 840, and a second source/drain interconnect 852 is formed which makes an electrical connection to the second source/drain contact 842. A shunt interconnect 899 is formed concurrently with the first source/drain interconnect 850 and the second source/drain interconnect 852; the shunt interconnect 899 makes an electrical connection to the substrate-side resistor contact 896 and extends into the shunt via 898 to make an electrical connection to the substrate 802. The pull-up/pull-down shunt 894 is connected in parallel across a first clamp, not shown, of the semiconductor device 800. The semiconductor device 800 may include another pull-up/pull-down shunt connected in parallel across a second clamp. Forming the pull-up/pull-down shunt 894 to have a resistor body in the two-dimensional electron gas in the low-defect layer 808, forming the substrate-side resistor contact 896 concurrently with the first source/drain contact 840 and the second source/drain contact 842, and forming the shunt interconnect 899 concurrently with the first source/drain interconnect 850 and the second source/drain interconnect 852 may advantageously reduce a fabrication cost and complexity of the semiconductor device 800.

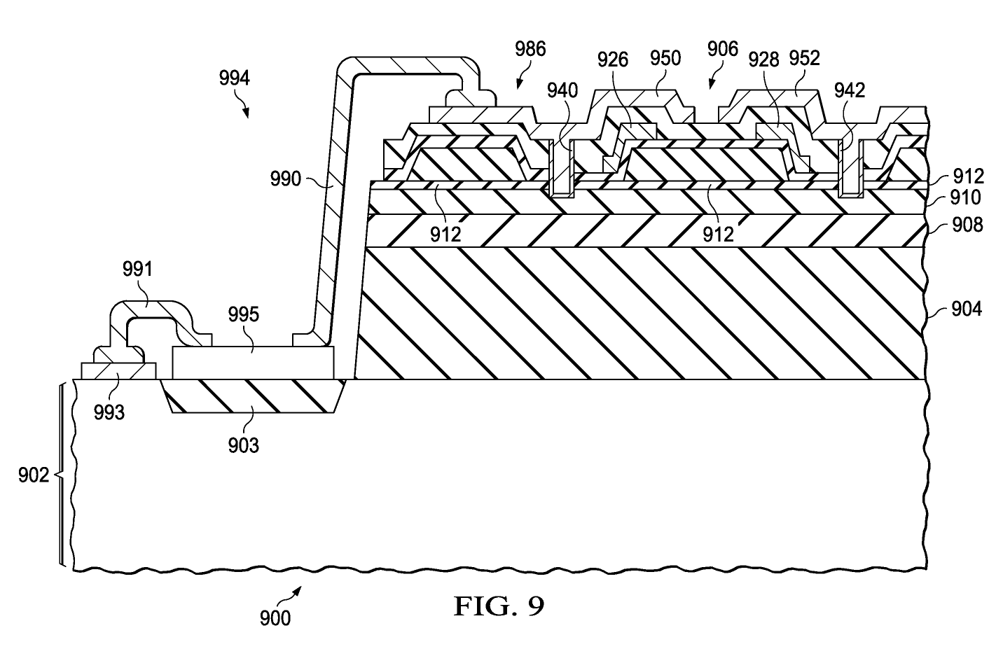

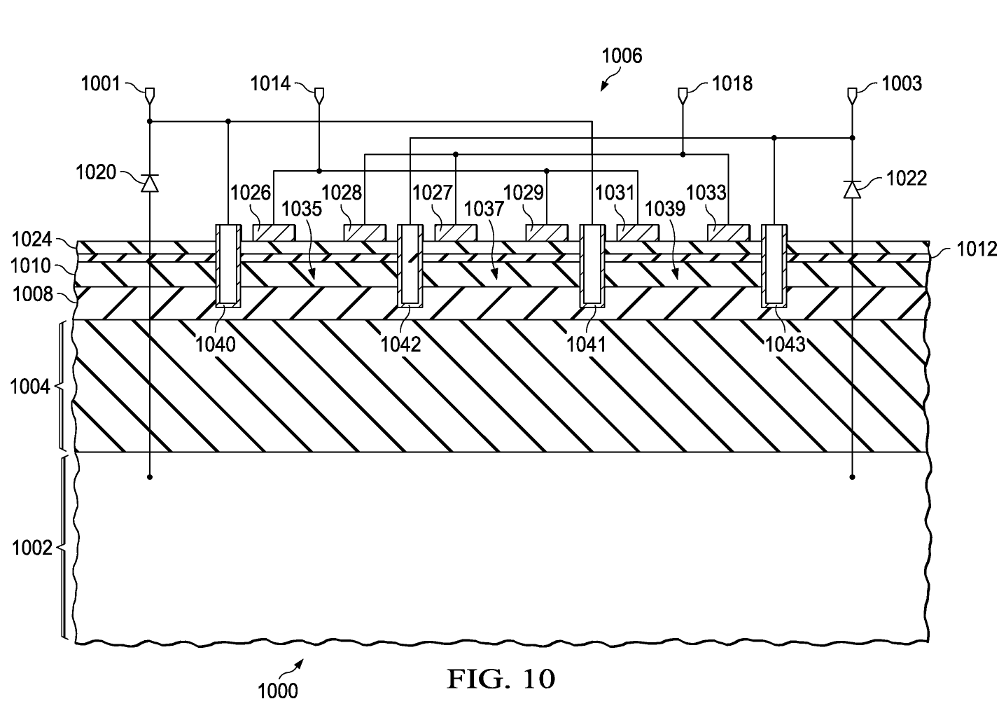

FIG. 9 is a cross section of another exemplary semiconductor device containing a bidirectional GaN FET, clamps and at least one pull-up/pull-down shunt. The semiconductor device 900 is formed on a non-insulating substrate 902 such as a silicon substrate. The substrate 902 includes a shunt isolation layer 903 in an area for the shunt 994. The shunt isolation layer 903 may be, for example, field oxide 903 formed by a shallow trench isolation (STI) process.

A III-N layer stack 904 is formed on the substrate 902 to provide a suitable surface for the bidirectional GaN FET 906. A low-defect layer 908 is formed on the III-N layer stack 904. A barrier layer 910 is formed on the low-defect layer 908. Forming the barrier layer 910 on the low-defect layer 908 generates a two-dimensional electron gas in the low-defect layer 908 just below the barrier layer 910. An optional cap layer 912 may be formed on the barrier layer 910. The III-N layer stack 904, the low-defect layer 908, the barrier layer 910 and the cap layer 912 may be, for example, similar to the III-N layer stack 404, the low-defect layer 408, the barrier layer 410 and the cap layer 412, respectively, of FIG. 4A.

The bidirectional GaN FET 906 is formed in and over the barrier layer 910, for example, as described in reference to FIG. 4A through FIG. 4E or in reference to FIG. 5A through FIG. 5E. The bidirectional GaN FET 906 includes a first gate 926 and a second gate 928, and a first source/drain contact 940 and a second source/drain contact 942. The first source/drain interconnect 950 includes a first shunt bonding pad 986 in the area for the shunt 994. An isolation etch process removes the cap layer 912, the barrier layer 910, the low-defect layer 908 and the III-N layer stack 904 outside an area for the bidirectional GaN FET 906, exposing the shunt isolation layer 903 in the substrate 902. The isolation etch process may be performed, for example, as described in reference to FIG. 5A.

A shunt resistor 995 is formed over the shunt isolation layer 903. The shunt resistor 995 may include, for example a resistor body of polycrystalline silicon, commonly referred to as polysilicon. A first electrical connection 990, for example a wirebond 990 as depicted in FIG. 9, is formed so as to connect the first shunt bonding pad 986 of the first source/drain interconnect 950 to first end of the shunt resistor 995. A second electrical connection 991, for example another wirebond 991, is formed so as to connect a second end of the shunt resistor 995 to the substrate (702, possibly through a bondpad 993 on the substrate 902. The pull-up/pull-down shunt 994 is connected in parallel across a first clamp, not shown, of the semiconductor device 900. The semiconductor device 900 may include another pull-up/pull-down shunt connected in parallel across a second clamp. Forming the shunt resistor 995 on the substrate 902 may advantageously facilitate integrating the pull-up/pull-down shunt 994 in a version of the semiconductor device 900 in which the substrate 902 is exposed by the isolation etch.

FIG. 10 is a cross section of an exemplary semiconductor device containing a bidirectional GaN FET with multiple pairs of gates, and two clamps. The semiconductor device 1000 is formed on a non-insulating substrate 1002 such as a silicon substrate. A III-N layer stack 1004 is formed on the substrate 1002 to provide a suitable surface for the bidirectional GaN FET 1006. A low-defect layer 1008 is formed on the III-N layer stack 1004. A barrier layer 1010 is formed on the low-defect layer 1008. Forming the barrier layer 1010 on the low-defect layer 1008 generates a two-dimensional electron gas in the low-defect layer 1008 just below the barrier layer 1010. An optional cap layer 1012 may be formed on the barrier layer 1010. A gate dielectric layer 1024 may be formed over the barrier layer 1010, on the cap layer 1012 if present. The III-N layer stack 1004, the low-defect layer 1008, the barrier layer 1010, the cap layer 1012 and the gate dielectric layer 1024 may be, for example, similar to the III-N layer stack 404, the low-defect layer 408, the barrier layer 410, the cap layer 412 and the gate dielectric layer 424, respectively, of FIG. 4A.

In the instant example, the GaN FET 1006 includes a plurality of instances of a first gate and a second gate and corresponding instances of a first source/drain contact and a second source/drain contact. The GaN FET 1006 includes a first instance 1040 of the first source/drain contact and a first instance 1026 of the first gate formed proximate to the first instance 1040 of the first source/drain contact, a first instance 1028 of the second gate separated from the first instance 1026 of the first gate by a first instance 1035 of a drift region of the GaN FET 1006, and a first instance 1042 of the second source/drain contact proximate to the first instance 1028 of the second gate.

The GaN FET 1006 includes a second instance 1027 of the second gate formed proximate to the first instance 1042 of the second source/drain contact, a second instance 1029 of the first gate separated from the second instance 1027 of the second gate by a second instance 1037 of the drift region, and a second instance 1041 of the first source/drain contact proximate to the second instance 1029 of the first gate.

The GaN FET 1006 further includes a third instance 1031 of the first gate formed proximate to the second instance 1041 of the first source/drain contact, a third instance 1033 of the second gate separated from the third instance 1031 of the first gate by a third instance 1039 of the drift region, and a second instance 1043 of the second source/drain contact proximate to the third instance 1033 of the second gate.

The semiconductor device 1000 includes a first clamp 1020 and a second clamp 1022, which may be formed, for example, according to any of the examples described herein. FIG. 10 depicts the first clamp 1020 and the second clamp 1022 as schottky diodes with substrate vias through the III-N layer stack 1004 to the substrate, as described in reference to FIG. 4A through FIG. 4E.

The first clamp 1020, the first instance 1040 of the first source/drain contact, and the second instance 1041 of the first source/drain contact are electrically coupled to a first source/drain terminal 1001 of the semiconductor device 1000, for example by interconnects of the semiconductor device 1000. The second clamp 1022, the first instance 1042 of the second source/drain contact, and the second instance 1043 of the second source/drain contact are similarly electrically coupled to a second source/drain terminal 1003 of the semiconductor device 1000. The first instance 1026 of the first gate, the second instance 1029 of the first gate, and the third instance 1031 of the first gate are electrically coupled to a first gate terminal 1014 of the semiconductor device 1000. The first instance 1028 of the second gate, the second instance 1027 of the second gate, and the third instance 1033 of the second gate are electrically coupled to a second gate terminal 1018 of the semiconductor device 1000. Forming the semiconductor device 1000 with multiple instances of the first gate and the second gate and corresponding instances of the first source/drain contact and the second source/drain contact, and two clamps, may advantageously provide a desired current density for the GaN FET 1006 while providing a desired area for the semiconductor device 1000.

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A semiconductor device, comprising:
a bidirectional gallium nitride field effect transistor (GaN FET) formed on III-N layers over a substrate, said substrate being non-insulating, said bidirectional GaN FET having a first source/drain node and a second source/drain node;
a first clamp connected between said first source/drain node and said substrate; and
a second clamp connected between said second source/drain node and said substrate.

2. The semiconductor device of claim 1, in which:
said first clamp comprises a first schottky diode and a first clamp interconnect of interconnect metal connected to said first source/drain node, said first clamp interconnect contacting a barrier layer of said III-N layers to form said first schottky diode; and
said second clamp comprises a second schottky diode and a second clamp interconnect of said interconnect metal connected to said second source/drain node, said second clamp interconnect contacting said barrier layer to form said second schottky diode.

3. The semiconductor device of claim 1, in which:
said first clamp comprises a first enhancement mode GaN FET and a first clamp interconnect of interconnect metal connected to a first clamp gate of said first enhancement mode GaN FET, said first clamp interconnect being electrically coupled to said substrate; and
said second clamp comprises a second enhancement mode GaN FET and a second clamp interconnect of interconnect metal connected to a second clamp gate of said second enhancement mode GaN FET, said second clamp interconnect being electrically coupled to said substrate.

4. The semiconductor device of claim 1, in which:
said substrate comprises a semiconductor material;
said first clamp comprises a first diode disposed in said semiconductor material of said substrate, such that an anode of said first diode is electrically coupled to said substrate and a cathode of said first diode is electrically coupled to said first source/drain node; and
said second clamp comprises a second diode disposed in said semiconductor material of said substrate, such that an anode of said second diode is electrically coupled to said substrate and a cathode of said second diode is electrically coupled to said second source/drain node.

5. The semiconductor device of claim 1, in which:
said first clamp comprises a first clamp via extending through said III-N layers to said substrate; and
said second clamp comprises a second clamp via extending through said III-N layers to said substrate.

6. The semiconductor device of claim 1, in which:
said first clamp comprises a first clamp interconnect extending over an edge of said III-N layers to said substrate; and
said second clamp comprises a second clamp interconnect extending over said edge of said III-N layers to said substrate.

7. The semiconductor device of claim 1, further comprising a pull-up/pull-down shunt connected in parallel across said first clamp.

8. The semiconductor device of claim 7, in which said pull-up/pull-down shunt comprises a resistor in a two-dimensional electron gas in a barrier layer of said III-N layers between a substrate-side resistor contact and said first source/drain node.

9. The semiconductor device of claim 7, in which said pull-up/pull-down shunt comprises an enhancement mode GaN FET.

10. The semiconductor device of claim 1, in which:
said first source/drain node and said second source/drain node of said bidirectional GaN FET comprise a series of alternating instances of said first source/drain node and said first source/drain node; and
said bidirectional GaN FET comprises a first gate and a second gate located between each pair of alternating instances of said first source/drain node and said first source/drain node, wherein said first gate is proximate to said instance of said first source/drain node and said second gate is proximate to said instance of said second source/drain node.

11. A method of forming a semiconductor device, comprising the steps of:
providing a substrate, said substrate being non-insulating;
forming III-N layers over said substrate;
forming a first gate of a bidirectional GaN FET over said III-N layers;
forming a second gate of said bidirectional GaN FET over said III-N layers;
forming a first source/drain contact of said bidirectional GaN FET in said III-N layers proximate to said first gate;
forming a second source/drain contact of said bidirectional GaN FET in said III-N layers proximate to said second gate;
forming a first clamp connected between said first source/drain contact and said substrate; and
forming a second clamp connected between said second source/drain contact and said substrate.

12. The method of claim 11, in which:
said step of forming said first clamp comprises forming a first clamp interconnect of interconnect metal connected to said first source/drain contact, so that said first clamp interconnect contacts a barrier layer of said III-N layers to form a first schottky diode of said first clamp; and
said step of forming said second clamp comprises forming a second clamp interconnect of interconnect metal connected to said second source/drain contact, so that said second clamp interconnect contacts said barrier layer to form a second schottky diode of said second clamp.

13. The method of claim 11, in which:
said step of forming said first clamp comprises forming a first clamp gate of a first enhancement mode GaN FET and forming a first clamp interconnect of interconnect metal so that first clamp interconnect is connected to said first clamp gate, and is coupled to said substrate; and
said step of forming said second clamp comprises forming a second clamp gate of a second enhancement mode GaN FET and forming a second clamp interconnect of said interconnect metal so that second clamp interconnect is connected to said second clamp gate, and is coupled to said substrate.

14. The method of claim 11, in which:
said substrate comprises a semiconductor material;
said step of forming said first clamp comprises forming a first diode in said semiconductor material of said substrate, such that an anode of said first diode is electrically coupled to said substrate, and forming an electrical connection between a cathode of said first diode and said first source/drain contact; and
said step of forming said second clamp comprises forming a second diode in said semiconductor material of said substrate, such that an anode of said second diode is electrically coupled to said substrate, and forming an electrical connection between a cathode of said second diode and said second source/drain contact.

15. The method of claim 11, in which:
said step of forming said first clamp comprises removing III-N material from said III-N layers to form a first clamp via hole which exposes said substrate and forming a first clamp via in said first clamp via hole, extending through said III-N layers to said substrate; and
said step of forming said second clamp comprises removing III-N material from said III-N layers to form a second clamp via hole which exposes said substrate and forming a second clamp via in said second clamp via hole, extending through said III-N layers to said substrate.

16. The method of claim 11, in which:
said step of forming said first clamp comprises removing III-N material from said III-N layers to expose said substrate, forming a layer of dielectric material over an edge of said III-N layers, and forming a first clamp interconnect over said layer of dielectric material extending over said edge of said III-N layers to said substrate; and
said step of forming said second clamp comprises forming a second clamp interconnect over said layer of dielectric material extending over said edge of said III-N layers to said substrate.

17. The method of claim 11, further comprising forming a pull-up/pull-down shunt, forming an electrical connection between said pull-up/pull-down shunt and said first source/drain node, and forming an electrical connection between said pull-up/pull-down shunt and said substrate.

18. The method of claim 17, in which said step of forming said pull-up/pull-down shunt comprises forming a substrate-side resistor contact to a two-dimensional electron gas in a barrier layer of said III-N layers so as to form a resistor in said two-dimensional electron gas between said substrate-side resistor contact and said first source/drain contact.

19. The method of claim 17, in which said step of forming said pull-up/pull-down shunt comprises forming an enhancement mode gate of a GaN FET over a barrier layer of said III-N layers.

20. The method of claim 12, in which:
said steps of forming said first source/drain node and forming said second source/drain node include forming a series of alternating instances of said first source/drain node and said first source/drain node; and
further comprising the step of forming a first gate and a second gate located between each pair of alternating instances of said first source/drain node and said first source/drain node, said first gate being formed proximate to said instance of said first source/drain node and said second gate being formed proximate to said instance of said second source/drain node.
